(19) United States
(12) Patent Application Publication
(10) Pub. No.: US 2016/0343992 A1
(43) Pub. Date: Nov. 24, 2016

(54) ORGANIC LIGHT-EMITTING DISPLAY DEVICE

(71) Applicant: SAMSUNG DISPLAY CO., LTD., Yongin-si (KR)

(72) Inventors: Gun Shik Kim, Yongin-si (KR); Soon Ryong Park, Sejong-si (KR); Chul Hyun Choi, Yongin-si (KR); Kwang Woo Lee, Yongin-si (KR)

(21) Appl. No.: 14/887,104

(22) Filed: Oct. 19, 2015

(30) Foreign Application Priority Data
May 22, 2015 (KR) 10-2015-0071720

(51) Int. Cl. H01L 51/52; H01L 27/32

(52) U.S. Cl. CPC H01L 51/5281; H01L 51/5237; H01L 51/5275; H01L 51/5284; H01L 27/322; H01L 27/3244; H01L 2251/5338

(57) ABSTRACT

An organic light-emitting display device that includes a substrate, first and second electrodes facing each other on the substrate, an organic light-emitting layer between the first and second electrodes, a thin-film encapsulation (TFE) film on the second electrode, a reflection reduction layer on the TFE film, and a refraction adjustment layer between the reflection reduction layer and the organic light-emitting layer.

### CROSS-REFERENCE TO RELATED APPLICATION

This application claims priority to, and the benefit of, Korean Patent Application No. 10-2015-0071720 filed on May 22, 2015 in the Korean Intellectual Property Office, the disclosure of which is incorporated herein by reference in its entirety.

### BACKGROUND

1. Field

The present disclosure relates to an organic-light emitting display device.

2. Description of the Related Art

Recently, organic light-emitting display devices have been used not only in small mobile devices, such as smartphones, but have also been used in large-screen televisions (TVs).

Organic light-emitting display devices are self-emissive display devices capable of displaying an image with the aid of organic light-emitting elements that emit light. More specifically, in an organic light-emitting display device, holes and electrons injected into an emission layer, which is between first and second electrodes, combine with each other to generate excitons, and light is generated due to energy generated upon the transition of the excitons from an excited state to a ground state.

### SUMMARY

Exemplary embodiments of the invention provide an organic light-emitting display device capable of improving light leakage.

Exemplary embodiments of the invention also provide an organic light-emitting display device capable of reducing or preventing internal light from scattering to be released from a white printed layer when a flexible substrate and a thin-film encapsulation (TFE) film are applied thereto.

However, exemplary embodiments of the invention are not restricted to those set forth herein. The above and other exemplary embodiments of the invention will become more apparent to one of ordinary skill in the art to which the invention pertains by referencing the detailed description of the invention given below.

According to an exemplary embodiment of the invention, there is provided an organic light-emitting display device including a substrate, first and second electrodes facing each other on the substrate, an organic light-emitting layer between the first and second electrodes, a thin-film encapsulation (TFE) film on the second electrode, a reflection reduction layer on the TFE film, and a refraction adjustment layer between the reflection reduction layer and the organic light-emitting layer.

The organic light-emitting display device may further include a window on the reflection reduction layer, the window including a protruding area that extends beyond the organic light-emitting layer, and a printed layer on a surface of the protruding area facing the substrate.

The printed layer may be white.

The organic light-emitting display device may further include a black matrix below the printed layer.

The refraction adjustment layer may have a lower refractive index than that of the reflection reduction layer.

A refractive index of the refraction adjustment layer may be in a range of about 1 to about 1.5.

A refractive index of the refraction adjustment layer may be in a range of about 1 to about 1.3.

The refraction adjustment layer may be between the reflection reduction layer and the TFE film.

The substrate may include a flexible material.

The substrate may include a polyimide material.

The refractive adjustment layer may include an adhesive component, and the reflection reduction layer and the TFE film may be bonded together by the refraction adjustment layer.

The reflection reduction layer may include a polarizing plate.

In another embodiment of the invention, there is provided an organic light-emitting display device including a substrate, first and second electrodes facing each other on the substrate, an organic light-emitting layer between the first and second electrodes, a thin-film encapsulation (TFE) film on the second electrode to encapsulate the first and second electrodes and the organic light-emitting layer, a color filter layer on the TFE film and comprising a light shielding pattern, a window on the color filter layer, and a refraction adjustment layer between the window and the organic light-emitting layer.

The organic light-emitting display device may further include a reflection reduction layer between the color filter layer and the window.

The refraction adjustment layer may be between the reflection reduction layer and the organic light-emitting layer.

The refraction adjustment layer may have a lower refractive index than that of the reflection reduction layer and that of the color filter layer.

A refractive index of the refraction adjustment layer may be in a range of about 1 to about 1.3.

The organic light-emitting display device may further include a printed layer, the window may include a protruding area that is not covered by the organic light-emitting layer, and the printed layer may be formed on a surface of the protruding area facing the substrate.

The printed layer may be white.

The substrate may include a flexible material.

According to the exemplary embodiments, it is possible to improve light leakage.

Also, it is possible to reduce or prevent light internal to an organic light-emitting display device from scattering to be released from a white printed layer in a case when a flexible substrate and a TFE film are applied.

Other features and exemplary embodiments will be apparent from the following detailed description, the drawings, and the claims.

### BRIEF DESCRIPTION OF THE DRAWINGS

FIG. 1 is a cross-sectional view illustrating an organic light-emitting display device according to an exemplary embodiment of the invention.

FIG. 2 is an enlarged cross-sectional view of the part A of FIG. 1.

FIG. 3 is an enlarged cross-sectional view of the part B of FIG. 2.

FIG. 4 is a cross-sectional view illustrating an organic light-emitting display device according to another exemplary embodiment of the invention.

FIG. 5 is a cross-sectional view illustrating an organic light-emitting display device according to another exemplary embodiment of the invention.

FIG. 6 is an enlarged cross-sectional view of the part C of FIG. 5.

### DETAILED DESCRIPTION

Features of the inventive concept and methods of accomplishing the same may be understood more readily by reference to the following detailed description of embodiments and the accompanying drawings. The inventive concept may, however, be embodied in many different forms and should not be construed as being limited to the embodiments set forth herein. Hereinafter, example embodiments will be described in more detail with reference to the accompanying drawings, in which like reference numbers refer to like elements throughout. The present invention, however, may be embodied in various different forms, and should not be construed as being limited to only the illustrated embodiments herein. Rather, these embodiments are provided as examples so that this disclosure will be thorough and complete, and will fully convey the aspects and features of the present invention to those skilled in the art. Accordingly, processes, elements, and techniques that are not necessary to those having ordinary skill in the art for a complete understanding of the aspects and features of the present invention may not be described. Unless otherwise noted, like reference numerals denote like elements throughout the attached drawings and the written description, and thus, descriptions thereof will not be repeated. In the drawings, the relative sizes of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present invention.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments only and is not intended to be limiting of the present invention. As used herein, the singular forms “a,” “an,” and “the” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

The electronic or electric devices and/or any other relevant devices or components according to embodiments of the present invention described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the exemplary embodiments of the present invention.

Embodiments are described herein with reference to cross-section illustrations that are schematic illustrations of idealized embodiments (and intermediate structures). As such, variations from the shapes of the illustrations as a result of, for example, manufacturing techniques and/or tolerances, are to be expected. Thus, these embodiments should not be construed as limited to the particular shapes of regions illustrated herein but are to include deviations in shapes that result, for example, from manufacturing. For example, a region illustrated as a rectangle may have rounded or curved features and/or a gradient at its edges rather than a binary change from the region. Thus, the regions illustrated in the figures are schematic in nature and their shapes are not intended to illustrate the actual shape of a region of a device and are not intended to limit the scope of the inventive concept.

Unless otherwise defined, all terms (including technical and scientific terms) used herein have the same meaning as commonly understood by one of ordinary skill in the art to which the inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

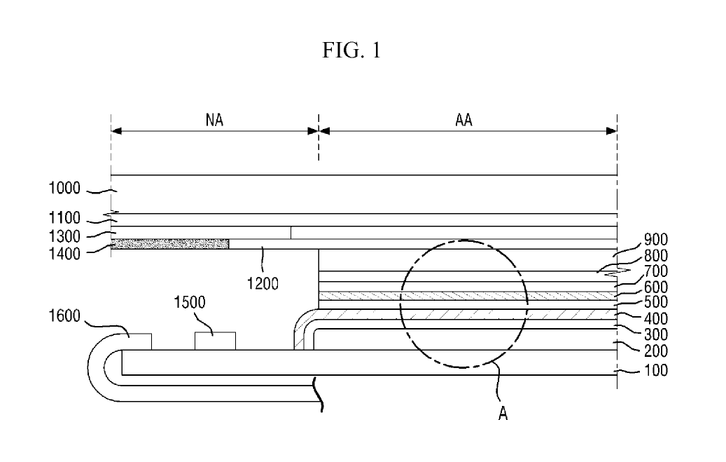

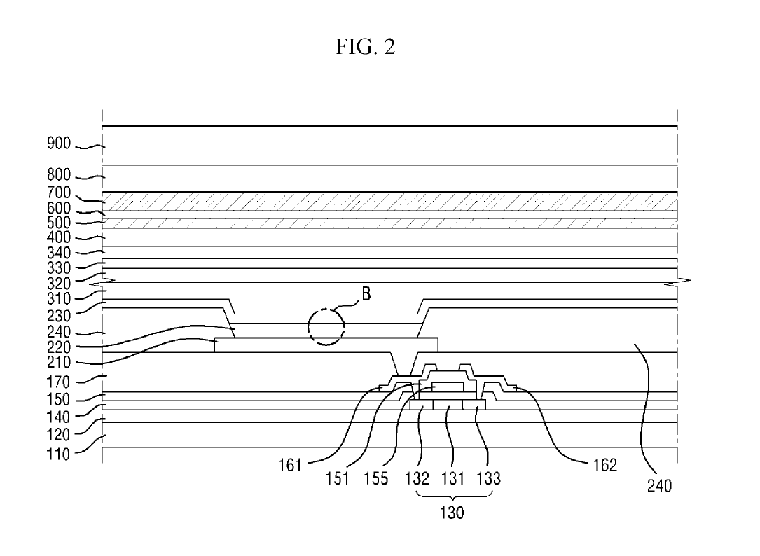

FIG. 1 is a cross-sectional view illustrating an organic light-emitting display device according to an exemplary embodiment of the invention, and FIG. 2 is an enlarged cross-sectional view of the part A of FIG. 1.

Referring to FIGS. 1 and 2, the organic light-emitting display device may include a substrate 110, first and second electrodes 210 and 230 facing each other above the substrate 110, an organic light-emitting layer 220 between the first and second electrodes 210 and 230, a thin-film encapsulation (TFE) film 400 above the second electrode 230 to encapsulate the first and second electrodes 210 and 230 and the organic light-emitting layer 220 in the space formed with the substrate 110, a reflection reduction/reflection prevention layer 700 above the TFE film 400, and a refraction adjustment layer 500 between the reflection reduction/reflection prevention layer 700 and the organic light-emitting layer 220.

The substrate 110 may include an insulating substrate. A semitransparent or opaque substrate and/or a transparent substrate may be used as the insulating substrate. The organic light-emitting display device according to the exemplary embodiment of FIG. 1 may be divided into a display area AA and a non-display area NA. In the display area AA of the substrate 110, element(s) for displaying an image, such as the organic light-emitting layer 220, may be provided. The substrate 110 may include a protruding area that extends into the non-display area NA from the display area AA.

The insulating substrate may be formed of a material such as glass, quartz or a polymer resin. Examples of the polymer resin material include polyethersulfone (PES), polyacrylate: (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT or TAC), cellulose acetate propionate (CAP) and/or a combination thereof.

In some exemplary embodiments, the insulating substrate may be formed of a flexible material. For example, the insulating substrate may be a flexible substrate formed of a flexible material, such as PI.

Thin-film transistor (TFT) devices may be formed on the substrate 110 so as to form a TFT array substrate 100. A substrate on which the elements of a TFT array are formed will hereinafter be referred to as the TFT array substrate 100. For convenience, the devices formed on the TFT array substrate 100 to drive the organic light-emitting layer 220 will hereinafter be collectively referred to as an organic light-emitting device layer 200.

A buffer layer 120 may be formed on the substrate 110 to reduce or prevent the infiltration of impurities or moisture, and to planarize the surface of the substrate 110. The buffer layer 120 is already well known in the art to which the invention pertains, and thus, a detailed description thereof will be omitted.

A semiconductor 130 may be formed on the buffer layer 120 using polycrystalline silicon. The semiconductor 130 may include a channel region 131, and source and drain regions 132 and 133, which are respectively formed on the sides of the channel region 131. The channel region 131 may be formed of polycrystalline silicon doped with no impurities, and the source and drain regions 132 and 133 may be formed of polycrystalline silicon doped with conductive impurities, i.e., an extrinsic semiconductor.

A gate insulating layer 140 may be formed on the semiconductor 130. The gate insulating layer 140 may be a single-layer or a multi-layer including silicon nitride or silicon oxide. A gate electrode 155 may be formed on the gate insulating layer 140, and the gate electrode 155 may overlap the channel region 131. An interlayer dielectric layer 150 may be formed on the gate electrode 155 and on the gate insulating layer 140. The interlayer dielectric layer 150 may be formed of the same material as the gate insulating layer 140. Contact holes may be formed at the gate insulating layer 140 and at the interlayer dielectric layer 150 to expose the source and drain regions 132 and 133, respectively, and source and drain electrodes 161 and 162 may be formed on the interlayer dielectric layer 150. The source electrode 161 may be connected to the source region 132 of the semiconductor 130 through one of the contact holes, and the drain electrode 162 may be connected to the drain region 133 through the other contact hole.

A protective layer 170 may be formed on the interlayer dielectric layer 150, and a contact hole may be formed at the protective layer 170 to expose the drain electrode 162. A first electrode 210, which is electrically connected to the drain electrode 162 via the contact hole of the protective layer 170, may be formed on the protective layer 170.

The first electrode 210, and a pixel-defining layer 240 that covers part of the first electrode 210 and that defines each pixel, may be formed on the protective layer 170. Each pixel may be defined by an opening in the pixel-defining layer 240, and the organic light-emitting layer 220 may be located in the opening. The pixel-defining layer 240 may be formed of a polyacrylic resin or polyimide-based resin, but the invention is not limited thereto.

The organic light-emitting layer 220 may be located in the opening defined by the pixel-defining layer 240. The organic light-emitting layer 220 is illustrated in FIG. 2 as being disposed only inside the opening in the pixel-defining layer 240, but the invention is not limited thereto. That is, some of the devices that form the organic light-emitting layer 220 may be additionally located on the pixel-defining layer 240.

A second electrode 230 may be formed on the organic light-emitting layer 220 and on the pixel-defining layer 240 to cover both of the organic light-emitting layer 220 and the pixel-defining layer 240.

The first electrode 210 may be disposed in each pixel of the organic light-emitting display device according to the exemplary embodiment of FIG. 1. The first electrode 210 may be an anode, and may include a conductive material with a larger work function than that of the second electrode 230. For example, the first electrode 210 may include a transparent material with a relatively large work function, such as indium tin oxide (ITO), indium zinc oxide (IZO), zinc oxide (ZnO), and/or indium oxide (In₂O₃).

The first electrode 210 may also include a reflective material such as, for example, silver (Ag), magnesium (Mg), aluminum (Al), platinum (Pt), plumbum (Pb), gold (Au), nickel (Ni), neodymium (Nd), iridium (Ir), chromium (Cr), lithium (Li), calcium (Ca) and/or a mixture thereof. Accordingly, the first electrode 210 may have a single-layer or a multi-layer structure including a conductive material and a reflective material. For example, the first electrode 210 may have an ITO/Mg, ITO/MgF, ITO/Ag, and/or ITO/Ag/ITO multi-layer structure, but the invention is not limited thereto.

The second electrode 230 may be a cathode, and may be a front electrode or a common electrode that is formed regardless of the distinction between pixels (e.g., that is formed over all of the pixels and the pixel-defining layer 240). The second electrode 230 may include a conductive material with a smaller work function than that of the first electrode 210.

The second electrode 230 may include Li, Ca, LiF/Ca, LiF/AI, Al, Mg, Ag, Pt, Pb, Ni, Au Nd, Ir, Cr, barium fluoride (BaF), barium (Ba) and/or a compound or mixture thereof (for example, a mixture of Ag and Mg). The second electrode 230 may alternatively include an auxiliary electrode. The auxiliary electrode may include a film formed through deposition using Li, Ca, LiF/Ca, LiF/AI, Al, Mg, Ag, Pt, Pd, Ni, Au Nd, Ir, Cr, BaF, Ba and/or a compound or mixture thereof, and a transparent metal oxide such as ITO, IZO, ZnO, indium tin zinc oxide (ITZO) and/or manganese dioxide (MnO₂) formed on the film.

The second electrode 230 may be formed by forming a thin conductive film with a small work function, and by depositing a transparent conductive film, such as an ITO, IZO, ZnO and/or In₂O₃ film, on the conductive film.

Because the second electrode 230 is formed of a transparent conductive material, light generated by the organic light-emitting layer 220 may be emitted forward through the second electrode 230 as a top emission-type organic light-emitting display device, but the invention is not limited thereto.

In an exemplary embodiment, a TFE film 400 may be above the second electrode 230, and may encapsulate the first electrode 210, the second electrode 230 and the organic light-emitting layer 220 in the space between the TFE film 400 and the substrate 110. As a result, the TFE film 400 may protect the devices, such as the organic light-emitting layer 220, from the exterior of the display device. A film formed of a resin-based material may be used as the TFE film 400. For example, a PI film, which has excellent heat resistance, chemical resistance, and insulation properties, may be used as the TFE film 400. By thinly forming the TFE film 400 using an inexpensive material such as PI, the thickness of the entire organic light-emitting display device according to the exemplary embodiment of FIG. 1 may be reduced. Also, due to the flexibility of PI, the TFE film 400 may exhibit excellent sealing capability even in a flexible organic light-emitting display device.

In a non-limiting example, a sealing layer, in which organic layers 310 and 330 and inorganic layers 320 and 340 are alternately stacked, may be additionally provided between the TFE film 400 and the second electrode 230 for planarization and for better sealing.

The reflection reduction/reflection prevention layer 700 may be located above the TFE film 400. The reflection reduction/reflection prevention layer 700, which reduces or prevents reflection of external light, may be implemented as a polarizing plate, although the invention is not limited thereto.

The refraction adjustment layer 500 may be located between the reflection reduction/reflection prevention layer 700 and the organic light-emitting layer 220. More specifically, as illustrated in FIG. 2, the refraction adjustment layer 500 may be interposed between the reflection reduction/reflection prevention layer 700 and the TFE film 400.

The refraction adjustment layer 500 may have a lower refractive index than the reflection reduction/reflection prevention layer 700. Light emitted from the organic light-emitting layer 220 may be entirely reflected in the organic light-emitting layer 220, and may thus travel toward a printed layer 1300 of the organic light-emitting display device, according to the exemplary embodiment of FIG. 1. Then, light reflected from the printed layer 1300 may be seen from outside the organic light-emitting display device (i.e., light leakage may occur). To address this problem, light totally reflected within the organic light-emitting layer 220 to travel toward the printed layer 1300 may be contained in the refraction adjustment layer 500, thereby effectively reducing light leakage.

The refraction adjustment layer 500 may have a refractive index from about 1 to about 1.5, or from about 1 to about 1.3. In response to the refractive index of the refraction adjustment layer 500 being in the range of about 1 to about 1.5, and particularly, in the range of about 1 to about 1.3, the refractive adjustment layer 500 may effectively contain light that would otherwise be totally reflected in the organic light-emitting layer 220 to travel toward an undesired direction.

A touch panel 900 may be above the reflection reduction/reflection prevention layer 700, and an adhesive member 800, which includes, for example, a transparent resin, may be interposed between the reflection reduction/reflection prevention layer 700 and the touch panel 900. The adhesive member 800 may include an optical clear resin (OCR), although the invention is not limited thereto.

The touch panel 900 may be formed of a transparent material to enable an image to be transmitted therethrough. The touch panel 900 may be, but is not limited to, a touch capacitive type, a resistive overlay type, an infrared beam type, an integral strain gauge type, a surface acoustic wave type, or a piezo electric type. The touch panel 900 is already well known in the field to which the invention pertains, and thus, a detailed description thereof will be omitted.

A window 1000 may be located above the touch panel 900, and may be formed of glass or a transparent polymer resin. The window 1000 may prevent devices in the display device, such as integrated circuits (ICs), from being damaged by external impact.

A bonding member 1200 may be provided between the window 1000 and the touch panel 900 to bond the window 1000 and the touch panel 900 together. The bonding member 1200 may be formed of a resin with high optical transmissivity, which may include, for example, an OCR, although the invention is not limited thereto. To maintain optical properties after the installation of the window 1000, the bonding member 1200 may be formed of a material having the same optical refractive index as, or a similar optical refractive index to, the window 1000, although the invention is not limited thereto. The bonding member 1200 may be formed of a photo-curable resin, for example, a ultraviolet (UV)-curable resin, although the invention is not limited thereto. That is, the bonding member 1200 may be formed of a thermosetting resin.

The window 1000 may include a protruding area, which does not overlap/which extends beyond the organic light-emitting layer 220 in a plan view, and the protruding area may correspond to the non-display area NA. The printed layer 1300 may be formed on the protruding area. That is, the printed layer 1300 may be formed on a surface of the non-display area NA of the window 1000 that faces the TFT array substrate 100. The printed layer 1300 may account for part of the non-display area NA visible to consumers, and may be referred to as a bezel. The printed layer 1300 may be formed in various designs and various colors according to consumers' needs.

The printed layer 1300 may surround the periphery of the display area AA on a horizontal plane of the organic light-emitting display device according to the exemplary embodiment of FIG. 1. That is, a bezel, which corresponds to the non-display area NA, may surround the periphery of the display area AA, and the printed layer 1300 may be formed to overlap the bezel.

A black matrix 1400 may be provided below the printed layer 1300 to contact the printed layer 1300 and to face the TFT array substrate 100. Accordingly, devices below the black matrix 1400, such as driving circuits, may be prevented from being viewed by a user from outside the organic light-emitting display device according to the exemplary embodiment of FIG. 1, and light reflected from such devices may be reduced or prevented from leaking out of the organic light-emitting display device according to the exemplary embodiment of FIG. 1. The black matrix 1400, like the printed layer 1300, may surround the periphery of the display area AA.

The printed layer 1300 may be white. Unlike a dark printed layer, a white printed layer, which has recently become popular according to consumers' needs, may not be able to properly absorb light, and may reflect light instead. Accordingly, light totally reflected within the organic light-emitting display device according to the exemplary embodiment of FIG. 1 may accidentally arrive at, and may be reflected from, the printed layer 1300, thereby causing light leakage. However, due to the presence of the refraction adjustment layer 500, the totally reflected light may be contained below the refraction adjustment layer 500, and may thus be prevented from traveling toward the printed layer 1300.

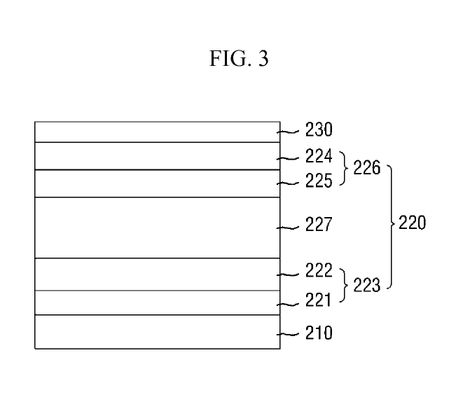

As discussed above, the TFT array substrate 100, unlike the organic light-emitting layer 200, etc., may have a protruding area that extends into the non-display area NA, and an integrated circuit (IC) chip 1500 may be mounted in the protruding area of the TFT array substrate 100. A flexible printed circuit board (FPCB) 1600 may be mounted in the protruding area of the TFT array substrate 100. Although not specifically illustrated, other devices or wires for driving the organic light-emitting display device according to the exemplary embodiment of FIG. 1 may also be formed in the protruding area of the TFT array substrate 100. The IC chip 1500, the FPCB 1600 and other devices that may be provided in the protruding area of the TFT array substrate 100 are already well known in the field to which the invention pertains, and detailed descriptions thereof will be omitted. FIG. 3 is an enlarged cross-sectional view of the part B of FIG. 2. Referring to FIG. 3, the organic light-emitting layer 220 may be interposed between the first electrode 210 and the second electrode 230.

The organic light-emitting layer 220 may have a structure in which a first charge transport region 223, an emission layer 227, and a second charge transport region 226 are sequentially arranged.

The first charge transport region 223 may have a single-layer structure including a single material, a single-layer structure including two or more different materials, or a multi-layer structure including two or more different materials. The first charge transport region 223 may additionally include a buffer layer and a first charge blocking layer. The first charge transport region 223 is illustrated in FIG. 3 as including a first charge injection layer 221 and a first charge transport layer 222, but the invention is not limited thereto. That is, one of the first charge injection layer 221 and the first charge transport layer 222 may be omitted, or the first charge injection layer 221 and the first charge transport layer 222 may be incorporated into a single layer.

The first charge injection layer 221 may be on the second electrode 210, and may improve the efficiency of the injection of holes from the second electrode 210 into the emission layer 227. More specifically, the first charge injection layer 221 may lower an energy barrier so that holes can be more effectively injected.

The first charge injection layer 221 may include a phthalocyanine compound such as copper phthalocyanine (CuPc), 4,4′,4″-tris(N-3-methylphenyl-N-phenylamino)triphenylamine) (m-MTDATA), 4,4′,4″-tris(diphenylamino)triphenylamine (TDATA), 4,4′,4″-tris[2-naphthyl(phenyl)-amino]triphenyl-amine (2-TNATA), polyaniline/dodecylbenzenesulfonic acid (PANI/DBSA), poly(3,4-ethylene dioxythiophene)/polystyrene sulfonate (PEDOT/PSS), polyaniline/camphorsulfonic acid (PANI/CSA), and/or polyaniline/polystyrene sulfonate (PANI/PSS).

The first charge transport layer 222 may be located on the first charge injection layer 221, and may deliver holes injected from the first charge injection layer 221 to the emission layer 227. The first charge transport layer 222 may have an optimum hole transfer efficiency in a case when the highest occupied molecular energy/highest occupied molecular orbital (HOMO) of the first charge transport layer 222 is substantially lower than the work function of the material of the second electrode 210, and is substantially higher than the HOMO of the emission layer 227. For example, the first charge transport layer 222 may include 4,4′-bis[N-(1-napthyl)-N-phenyl-amino]biphenyl (NPD), N,N′-diphenyl-N,N′-bis[3-methylphenyl]-1,1′-biphenyl-4,4′-diamine (TPD), 2,2′,7,7′-tetrakis-(N,N-diphenylamino)-9,9′-spirobifluoren (s-TAD), and/or 4,4′,4″-tris(N-3-methylphenyl-N-phenylamino)triphenylamine (m-MTDATA), but the invention is not limited thereto.

The first charge transport region 223 may also include a charge-generating material to improve conductivity. The charge-generating material may be uniformly or non-uniformly distributed in the first charge transport region 223. The charge-generating material may be, for example, a p-type dopant. The p-type dopant may be one of quinone derivatives, metal oxides and cyano-containing compounds, but the invention is not limited thereto. Non-limiting examples of the p-type dopant may include quinone derivatives such as tetracyanoquinodimethane (TCNQ) and 2,3,5,6-tetrafluoro-tetracyanoquinodimethane (F4-TCNQ) and metal oxides such as tungsten oxide and molybdenum oxide.

As mentioned above, the first charge transport region 223 may also include at least one of a buffer layer and a first charge blocking layer. The buffer layer may compensate for the optical resonance distance according to the wavelength of light emitted from the emission layer 227, thereby increasing light-emission efficiency. The buffer layer may include a material that may also be included in the first charge transport region 223. The first charge blocking layer may prevent charges from the second charge transport region 226 from being injected into the first charge transport region 223.

The emission layer 227 may be on the first charge transport region 223. The emission layer 227 may be formed of any material that is commonly used to form an emission layer. For example, the emission layer 227 may be formed of a material that emits red, green and blue light. The emission layer 227 may include a fluorescent material or a phosphorescent material.

In an exemplary embodiment, the emission layer 227 may include a host and a dopant.

For example, tris(8-hydroxyquinolinato) aluminum(III) (Alq3), 4,4′-N,N′-dicarbazole-biphenyl (CBP), poly(N-vinylcarbazole) (PVK), 9,10-bis(2-naphthalenyl)anthracene (ADN), 4,4′,4″-tris(N-carbazolyl)triphenylamine (TCTA), 1,3,5-tris(N-phenylbenzimiazole-2-yl)benzene (TPBi), 2-(t-butyl)-9, 10-bis (20-naphthyl) anthracene (TBADN), distyrylarylene (DSA), 4,4′-bis(9-carbazolyl)-2,2′-dimethyl-biphenyl (CDBP), and/or 2-methyl-9,10-bis(naphthalen-2-yl)anthracene (MADN) may be used as the host.

A fluorescent dopant and a phosphorescent dopant may both be used as the dopant. The type of the dopant may vary depending on the color rendered by the emission layer 227.

For example, a fluorescent material including 2-biphenyl-4-yl-5-(4-t-butylphenyl)-1,3,4-oxadiazole:tris(dibenzoylmethane)mono(1,10-phenanthroline)europium(III) (PBD:Eu(DBM)3(Phen)) or perylene may be selected as a red dopant. Alternatively, a phosphorescent material including a metal complex, such as bis(1-phenylisoquinoline)acetylacetonate iridium (PIQIr(acac)), bis(1-phenylquinoline)acetylacetonate iridium (PQIr(acac)), tris(1-phenylquinoline)iridium (PQIr) or octaethylporphyrin platinum (PtOEP)), and/or an organometallic complex may be selected as the red dopant.

For example, a fluorescent material containing Alq₃ may be selected as a green dopant. Alternatively, a phosphorescent material such as fac-tris(2-phenylpyridine)iridium (Ir(ppy)₃), bis(2-phenylpyridine)(acetylacetonate)iridium(III) (Ir(ppy)₂(acac)), and/or 2-phenyl-4-methyl-pyridine iridium (Ir(mpyp)₃) may be selected as the green dopant.

For example, a fluorescent material including one selected from the group including spiro-4,′-bis(2,2′-diphenylvinyl)1,1′-biphenyl (spiro-DPVBi), spiro-six phenyl (spiro-6P), distyrylbenzene (DSB), distyrylarylene (DSA), a polyfluorene (PFO)-based polymer and a poly p-phenylene vinylene (PPV)-based polymer may be selected as a blue dopant. Alternatively, a phosphorescent material such as bis[2-(4,6-difluorophenyl)pyridinato-N,C2′]iridium picolinate (F₂Irpic), bis[2-(4,6-difluorophenyl)pyridinato-N,C2′]iridium 2,2,6,6-tetramethylheptane-3,5-dione ((F₂ppy)₂Ir(tmd)), and/or tris[1-(4,6-difluorophenyl)pyrazolate-N,C2′]iridium (Ir(dfppz)₃) may be selected as the blue dopant.

The second charge transport region 226 may be on the emission layer 227. The second charge transport region 226 may have a single-layer structure including a single material, a single-layer structure including a plurality of different materials, or a multi-layer structure including a plurality of different materials. The second charge transport region 226 may also include a second charge blocking layer. The second charge transport region 226 is illustrated in FIG. 3 as including a second charge transport layer 225 and a second charge injection layer 224, but the invention is not limited thereto. That is, one of the second charge transport layer 225 and the second charge injection layer 224 may be optional, and may thus be omitted, or the second charge transport layer 225 and the second charge injection layer 224 may be incorporated into a single layer.

The second charge transport layer 225 may be on the emission layer 227, and may deliver holes injected from the second charge injection layer 224 to the emission layer 227.

For example, the second charge transport layer 225 may include Alq₃, TPBi, 2,9-dimethyl-4,7-diphenyl-1,10-phenanthroline (BCP), 4,7-diphenyl-1,10-phenanthroline (Bphen), 3-(Biphenyl-4-yl)-5-(4-tert-butylphenyl)-4-phenyl-4H-1,2,4-triazole (TAZ), 4-(naphthalen-1-yl)-3,5-diphenyl-4H-1,2,4-triazole), tBu-PBD(2-(4-biphenylyl)-5-(4-tert-butyl-phenyl)-1,3,4-oxadiazole (NTAZ), bis(2-methyl-8-quinolinolato-N1,O8)-(1,1′-Biphenyl-4-olato)aluminum (BAIq), bis(10-hydroxybenzo[h]quinolinato)beryllium (Bebq₂), ADN, and/or a mixture thereof, but the invention is not limited thereto.

The second charge injection layer 224 may be on the second charge transport layer 225, and may improve the efficiency of the injection of electrons from the second electrode 230 into the emission layer 227.

The second charge injection layer 224 may be formed of a lanthanide metal such as LiF, LiQ, Li₂O, BaO, NaCl, CsF, or Yb or a halide metal such as RbCl, Rbl, but the invention is not limited thereto. The second charge injection layer 224 may be formed of a mixture of the lanthanide metal or the halide metal and an insulating organometallic salt. The organometallic salt may be a material with an energy band gap of about 4 eV or higher. For example, the organometallic salt may include metal acetate, metal benzoate, metal acetoacetate, metal acetylacetonate or metal stearate.

The second charge transport region 226 may also include the second charge blocking layer. The second charge blocking layer may include at least one of BCP and Bphen, but the invention is not limited thereto.

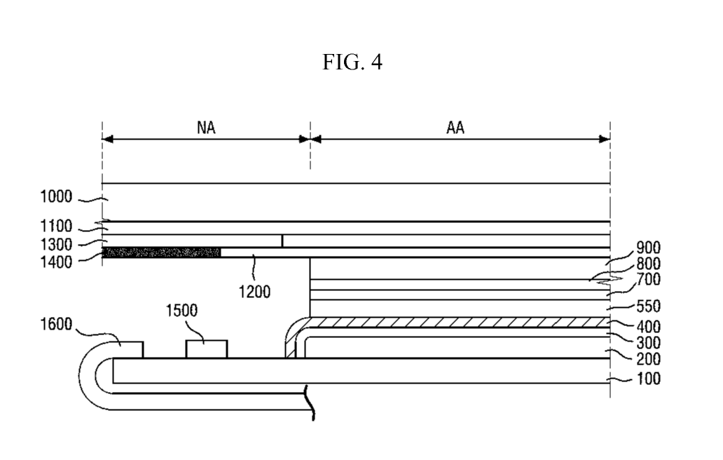

FIG. 4 is a cross-sectional view illustrating an organic light-emitting display device according to another exemplary embodiment of the invention.

In the organic light-emitting display device according to the exemplary embodiment of FIG. 1, an adhesive 600 is provided between the refraction adjustment layer 500 and the reflection reduction/reflection prevention layer 700 to bond the refraction adjustment layer 500 and the reflection reduction/reflection prevention layer 700 together. On the other hand, in the organic light-emitting display device according to the exemplary embodiment of FIG. 4, a refraction adjustment layer 550 having an adhesive component is provided, and can thus bond a reflection reduction/reflection prevention layer 700 and a TFE film 400 together without the aid of an additional adhesive. However, the invention is not limited to the exemplary embodiments of FIGS. 1 and 4. That is, the refraction adjustment layer 550 may be located between the TFE film 400 and an organic light-emitting layer 220, or may be located between the reflection reduction/reflection prevention layer 700 and the organic light-emitting layer 220. Other elements of the organic light-emitting display device according to the exemplary embodiment of FIG. 4 are the same as their respective counterparts of the organic light-emitting display device according to the exemplary embodiment of FIG. 1, and thus, detailed descriptions thereof will be omitted.

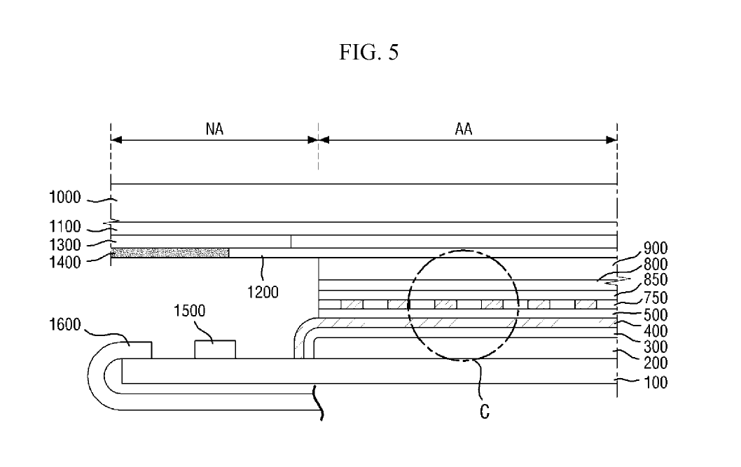

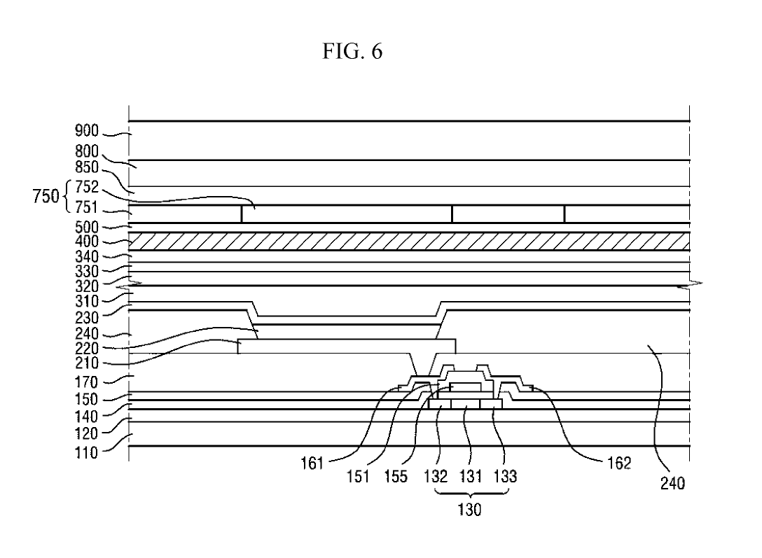

FIG. 5 is a cross-sectional view illustrating an organic light-emitting display device according to another exemplary embodiment of the invention, and FIG. 6 is an enlarged cross-sectional view of the part C of FIG. 5.

Referring to FIGS. 5 and 6, the organic light-emitting display device may include a substrate 110, first and second electrodes 210 and 230 above the substrate 110 to face each other, an organic light-emitting layer 220 between the first and second electrodes 210 and 230, a TFE film 400 above the second electrode 230 to encapsulate the first and second electrodes 210 and 230 and the organic light-emitting layer 220 in the space formed with the substrate 110, a color filter layer 750 having a light shielding pattern 751, a window 1000 above the color filter layer 750, and a refraction adjustment layer 400 between the window 1000 and the organic light-emitting layer 220.

The substrate 100 may be a TFT array substrate on which TFT devices are formed, an organic light-emitting device layer 200 may be formed on the TFT array substrate 100, and the TFE film 400 may be formed above the organic light-emitting device layer 200. The TFT array substrate 100, the organic light-emitting display layer 200, and the TFE film 400 have already been described above, and thus, detailed descriptions thereof will be omitted.

The color filter layer 750 may be located above the TFE film 400, and a refraction adjustment layer 500 may be interposed between the color filter layer 750 and the TFE film 400.

The color filter layer 750 may include a color filter 752, which respectively corresponds to each pixel, and the light shielding pattern 751, which is formed at a part of the color filter layer 750 that does not correspond to the organic light-emitting layer 220 formed in each pixel, and the color filter 752 and the light shielding pattern 751 may be alternately arranged. That is, the light shielding pattern 751 may be formed to correspond to a pixel-defining layer 240.

As mentioned above, the reflection of external light incident into the organic light-emitting display device, according to the exemplary embodiment of FIGS. 5 and 6, may be effectively reduced or prevented by forming the light shielding pattern 751. To more effectively reduce or prevent the reflection of external light, a reflection reduction/reflection prevention layer 850 may be formed on the color filter layer 750. The reflection reduction/reflection prevention layer 850 may be a thin layer in which at least one metal layer and at least one dielectric layer are alternately stacked, but the invention is not limited thereto.

The reflection reduction/reflection prevention layer 850 is illustrated in FIG. 5 as being formed on the color filter layer 750, although the invention is not limited thereto. If the light shielding pattern 751 included in the color filter layer 750 properly performs a reflection reduction/reflection prevention function, the reflection reduction/reflection prevention layer 850, which is located on the color filter layer 750, may be omitted.

The refraction adjustment layer 500 may have a lower refractive index than the color filter layer 750. More specifically, the refraction adjustment layer 500 may have a lower refractive index than the color filter 752 of the color filter layer 750. In a case when the reflection reduction/reflection prevention layer 850 is provided, the refraction adjustment layer 500 may have a refractive index that is lower than that of the color filter layer 750, and lower than that of the reflection reduction/reflection prevention layer 850 as well. For example, the refraction adjustment layer 500 may have a refractive index of about 1 to about 1.5 or about 1 to about 1.3. The refraction adjustment layer 500 may be located between the reflection reduction/reflection prevention layer 850 and the organic light-emitting layer 220.

The refraction adjustment layer 500 is illustrated in FIGS. 5 and 6 as being between the color filter layer 750 and the organic light-emitting layer 220, but the invention is not limited thereto. That is, the refraction adjustment layer 500 may be located between the color filter layer 750 and the reflection reduction/reflection prevention layer 850.

As described above, a device having a reflection reduction/prevention function, and a refraction adjustment layer having a lower refractive index than the device having the reflection reduction/prevention function, may be formed in an organic light-emitting display device. Accordingly, it is possible to reduce or prevent light emitted from an organic light-emitting layer from being viewed by a user from outside the organic light-emitting display device by being totally reflected to reach a printed layer and scatter. Thus, it is possible to improve light leakage, even for a flexible organic light-emitting display device using a flexible substrate and a TFE film.

While the inventive concept has been particularly shown and described with reference to exemplary embodiments thereof, it will be understood by those of ordinary skill in the art that various changes may be made therein without departing from the spirit and scope of the inventive concept as defined by the following claims. The exemplary embodiments should be considered in a descriptive sense only and not for purposes of limitation.

What is claimed is:

1. An organic light-emitting display device comprising:
a substrate;
first and second electrodes facing each other on the substrate;
an organic light-emitting layer between the first and second electrodes;
a thin-film encapsulation (TFE) film on the second electrode;
a reflection reduction layer on the TFE film; and
a refraction adjustment layer between the reflection reduction layer and the organic light-emitting layer.

2. The organic light-emitting display device of claim 1, further comprising:
a window on the reflection reduction layer, the window comprising a protruding area that extends beyond the organic light-emitting layer, and
a printed layer on a surface of the protruding area facing the substrate.

3. The organic light-emitting display device of claim 2, wherein the printed layer is white.

4. The organic light-emitting display device of claim 2, further comprising a black matrix below the printed layer.

5. The organic light-emitting display device of claim 1, wherein the refraction adjustment layer has a lower refractive index than that of the reflection reduction layer.

6. The organic light-emitting display device of claim 5, wherein a refractive index of the refraction adjustment layer is in a range of about 1 to about 1.5.

7. The organic light-emitting display device of claim 5, wherein a refractive index of the refraction adjustment layer is in a range of about 1 to about 1.3.

8. The organic light-emitting display device of claim 1, wherein the refraction adjustment layer is between the reflection reduction layer and the TFE film.

9. The organic light-emitting display device of claim 1, wherein the substrate comprises a flexible material.

10. The organic light-emitting display device of claim 9, wherein the substrate comprises a polyimide material.

11. The organic light-emitting display device of claim 1, wherein the refractive adjustment layer comprises an adhesive component, and
wherein the reflection reduction layer and the TFE film are bonded together by the refraction adjustment layer.

12. The organic light-emitting display device of claim 1, wherein the reflection reduction layer comprises a polarizing plate.

13. An organic light-emitting display device, comprising:
a substrate;
first and second electrodes facing each other on the substrate;
an organic light-emitting layer between the first and second electrodes;
a thin-film encapsulation (TFE) film on the second electrode to encapsulate the first and second electrodes and the organic light-emitting layer;
a color filter layer on the TFE film and comprising a light shielding pattern;
a window on the color filter layer; and
a refraction adjustment layer between the window and the organic light-emitting layer.

14. The organic light-emitting display device of claim 13, further comprising a reflection reduction layer between the color filter layer and the window.

15. The organic light-emitting display device of claim 14, wherein the refraction adjustment layer is between the reflection reduction layer and the organic light-emitting layer.

16. The organic light-emitting display device of claim 14, wherein the refraction adjustment layer has a lower refractive index than that of the reflection reduction layer and that of the color filter layer.

17. The organic light-emitting display device of claim 16, wherein a refractive index of the refraction adjustment layer is in a range of about 1 to about 1.3.

18. The organic light-emitting display device of claim 13, further comprising a printed layer,
wherein the window comprises a protruding area that is not covered by the organic light-emitting layer, and
wherein the printed layer is formed on a surface of the protruding area facing the substrate.

19. The organic light-emitting display device of claim 18, wherein the printed layer is white.

20. The organic light-emitting display device of claim 13, wherein the substrate comprises a flexible material.
